(19) United States
(12) Patent Application Publication
(10) Pub. No.: US 2026/0020223 A1
(43) Pub. Date: Jan. 15, 2026

(54) CAPACITOR, ELECTRONIC DEVICE INCLUDING THE SAME, AND METHOD OF PREPARING THE SAME

(71) Applicants: Samsung Electronics Co., Ltd., Suwon-si (KR); AJOU UNIVERSITY INDUSTRY-ACADEMIC COOPERATION FOUNDATION, Suwon-si (KR)

(72) Inventors: Donghyun KIM, Suwon-si (KR); Ilkwon OH, Suwon-si (KR); Sunghyun KIM, Suwon-si (KR); Jeonggyu SONG, Suwon-si (KR); Jooho LEE, Suwon-si (KR); Byoungjun WON, Suwon-si (KR); Minjeong RHEE, Suwon-si (KR); Youngjin LIM, Suwon-si (KR)

(73) Assignees: Samsung Electronics Co., Ltd., Suwon-si (KR); AJOU UNIVERSITY INDUSTRY-ACADEMIC COOPERATION FOUNDATION, Suwon-si (KR)

(21) Appl. No.: 19/018,410

(22) Filed: Jan. 13, 2025

(30) Foreign Application Priority Data
Jul. 10, 2024 (KR) 10-2024-0091384

(51) Int. Cl. H10B 12/00

(52) U.S. Cl. CPC H10B 12/315; H10B 12/033

(57) ABSTRACT

Provided are a capacitor, an electronic device including the same, and a method of preparing a capacitor, the capacitor including a first electrode, a second electrode opposing the first electrode, and a dielectric layer between the first and second electrodes, wherein the dielectric layer includes an insertion layer disposed within the dielectric layer, the insertion layer including an impurity and an aluminum oxide, and the impurity including a nonmetal element belonging to Group 1 or Group 17 in the Periodic Table of the Elements, wherein a content of the impurity may be greater than 0 at % and less than 1 at %, as a ratio of the number of atoms of the impurity to the total number of atoms of the impurity and metal within the insertion layer.

### CROSS-REFERENCE TO RELATED APPLICATION

This application is based on and claims priority under 35 U.S.C. § 119 to Korean Patent Application No. 10-2024-0091384, filed on Jul. 10, 2024, in the Korean Intellectual Property Office, the disclosure of which is incorporated by reference herein in its entirety.

### BACKGROUND

### 1. Field

The present disclosure relates to a capacitor, an electronic device including the same, and a method of preparing the same.

### 2. Description of the Related Art

Semiconductor devices such as memory and transistors are used in a variety of household and industrial equipment. With the advancement of higher-performance household and industrial devices, semiconductor devices are becoming more highly integrated and/or miniaturized.

As semiconductor devices become more highly integrated and/or miniaturized, the size available for such semiconductor devices decreases. However, as the size of capacitors decreases, the capacitance of capacitors diminishes and/or leakage current increases, prompting various proposed solutions to address these issues. For instance, the capacitance of a capacitor may be maintained by increasing the electrode area, reducing the thickness of the dielectric to change the capacitor's structure, improving the dielectric constants of the dielectric, and/or improving the capacitor manufacturing process.

### SUMMARY

There are limits to maintaining capacitor capacitance through structural improvements such as increasing the electrode area of capacitors or reducing the thickness of the dielectric, or through improvements in the manufacturing process. Suppressing the leakage current of capacitors may be advantageous. One method to improve the leakage current characteristics of capacitors may be by inserting alumina (Al₂O₃) into the dielectric layer. Alumina, due to its lower dielectric constant value, may have the limitation of lowering the overall dielectric constant of the dielectric layer. Therefore, a method may be advantageous that can suppress leakage current while reducing or preventing a decrease in the dielectric constant of the dielectric layer.

Provided is a capacitor in which leakage current is suppressed and/or dielectric constant degradation is reduced or prevented by including an impurity and an aluminum oxide in the insertion layer.

Provided is an electronic device including the dielectric.

Provided is a method of preparing the capacitor.

Additional aspects will be set forth in part in the description which follows and, in part, will be apparent from the description, or may be learned by practice of the presented embodiments of the disclosure.

According to an aspect of the disclosure, a capacitor includes a first electrode, a second electrode opposing the first electrode, and a dielectric layer between the first electrode and the second electrode, the dielectric layer including an insertion layer in the dielectric layer such that the insertion layer is spaced apart from the first and second electrodes, wherein the insertion layer includes an impurity and an aluminum oxide, wherein the impurity includes a nonmetal element belonging to Group 1 or Group 17 in the Periodic Table of the Elements, and wherein a content of the impurity is greater than 0 atomic percent (at %) and less than 1 at %, as a ratio of the number of impurity atoms to the total number of impurity and metal atoms in the insertion layer.

According to another aspect of the disclosure, an electronic device includes a transistor, and a capacitor electrically connected to the transistor, wherein the capacitor includes a first electrode, a second electrode opposing the first electrode, and a dielectric layer between the first electrode and the second electrode, the dielectric layer includes an insertion layer in the dielectric layer such that the insertion layer is spaced apart from the first and second electrodes, wherein the insertion layer includes an impurity and an aluminum oxide, wherein the impurity includes a nonmetal element belonging to Group 1 or Group 17 in the Periodic Table of the Elements, and wherein a content of the impurity is greater than 0 at % and less than 1 at %, as a ratio of the number of impurity atoms to the total number of impurity and metal atoms in the insertion layer.

According to another aspect of the disclosure, a method of preparing a capacitor includes providing a crystallized first dielectric material layer, a surface of the first dielectric material layer including a plurality of grains and grain boundaries therebetween, selectively adsorbing an impurity onto the grain boundaries, selectively adsorbing a first metal-containing inhibitor onto the plurality of grains, selectively introducing an aluminum oxide onto the grain boundaries, forming an insertion layer by oxidizing the first metal-containing inhibitor, and providing a second dielectric material layer on the insertion layer, wherein the impurity includes a nonmetal element belonging to Group 1 or Group 17 in the Periodic Table of the Elements.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a scanning electron microscope image of the surface of a fluorine-introduced ZrO₂ layer;

FIG. 2A is an image showing an XPS analysis profile of an F 1s orbital of the surface of a fluorine-introduced ZrO₂ layer;

FIG. 2B is an image showing the XPS analysis profile of an F 1s orbital of an etched surface after sputtering at 1,000 eV for 10 seconds onto the surface of a fluorine-introduced ZrO₂ layer;

FIG. 3A shows a reaction equation for forming Zr(OH)₃F+CF₃OH from Zr(OH)₄+CF₄;

FIG. 3B shows a reaction equation for forming Zr(OH)₃OF+CF₃H from Zr(OH)₄+CF₄;

FIG. 4A shows a reaction equation for forming Zr(OH)₃OCpZr(N(CH₃)₂)₂+HN(CH₃)₂ from Zr(OH)₄+CpZr(N(CH₃)₂)₃;

FIG. 4B shows a reaction equation for forming Zr(OH)₃CpZr(N(CH₃)₂)₂+FN(CH₃)₂ from FZr(OH)₃+CpZr(N(CH₃)₂)₃;

FIG. 5A shows a reaction equation for forming Zr(OH)₃OAl(CH₃)₂(OC₃H₇)+CH₄ from Zr(OH)₄+Al(CH₃)₂(OC₃H₇);

FIG. 5B shows a reaction equation for forming Zr(OH)₃OAl(CH₃)₂+FOC₃H₇ from FZr(OH)₃+Al(CH₃)₂(OC₃H₇);

FIG. 6 is a cross-sectional view showing the schematic structure of a capacitor according to at least one embodiment;

FIG. 7 is a cross-sectional view showing the schematic structure of a capacitor according to at least one embodiment;

FIG. 8 is a circuit diagram illustrating a schematic circuit configuration and operation of an electronic device employing a capacitor according to at least some embodiments;

FIG. 9 is a schematic diagram illustrating an electronic device according to at least one embodiment;

FIG. 10 is a schematic diagram illustrating an electronic device according to at least one embodiment;

FIG. 11 is a plan view illustrating an electronic device according to at least one embodiment;

FIG. 12 is a cross-sectional view taken along line A-A′ of FIG. 11;

FIG. 13 is a cross-sectional view illustrating an electronic device according to at least one embodiment;

FIGS. 14 and 15 are each a conceptual diagram schematically showing a device architecture applicable to a device, according to at least one embodiment; and

FIGS. 16A to 16G are each a schematic diagram showing a method of preparing a capacitor according to at least one embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The present inventive concepts, which will be more fully described hereinafter, may have various variations and various embodiments, and specific embodiments will be illustrated in the accompanied drawings and described in greater detail. However, the present inventive concept should not be construed as being limited to specific embodiments set forth herein. Rather, these embodiments are to be understood as encompassing all variations, equivalents, or alternatives included in the scope of the present inventive concept.

The terminology used hereinbelow is used for the purpose of describing particular embodiments only, and is not intended to limit the present inventive concept. As used herein, the singular forms are intended to include the plural forms as well, unless the context clearly indicates otherwise. As used herein, the terms “comprises” and/or “comprising,” or “includes” and/or “including” specify the presence of stated features, regions, integers, steps, operations, elements, components, ingredients, materials, or combinations thereof, but do not preclude the presence or addition of one or more other features, regions, integers, steps, operations, elements, components, ingredients, materials, or combinations thereof. As used herein, “/” may be interpreted as “and”, or as “or” depending on the context.

In the drawings, thicknesses may be magnified or exaggerated to clearly illustrate various layers and regions. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, whenever a range of values is enumerated, the range includes all values within the range as if recorded explicitly clearly, and may further include the boundaries of the range. Accordingly, the range of “X” to “Y” and/or “X or greater and Y or less” includes all values between X and Y, including X and Y. In contrast, the range of “greater than X and less than Y” includes all detectable values between X and Y excluding X and Y.

Throughout the specification, when a component, such as a layer, a film, a region, or a plate, is described as being “above” or “on” another component, the component may be directly above the other component, or there may be yet another component therebetween. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. Although the terms “first,” “second,” etc. may be used herein to describe various elements, these elements should not be limited by these terms. These terms are only used to distinguish one element from another element. In the present specification and the drawings, elements that serve substantially the same function are labeled with the same reference numeral and may not be discussed redundantly.

Also, in the specification, terms like “units” which denote and/or describe functional elements that process at least one function or operation, may be realized by processing circuitry such as, hardware, software, or a combination of hardware and software. For example, the processing circuitry may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc.

The lines or connecting members between components depicted in the drawings are illustratively shown as functional connections and/or physical or circuit connections. In actual devices, these may be represented as various alternative or additional functional, physical, or circuit connections.

The use of all examples or exemplary terminology is merely for the purpose of detailing the technical concept, and unless limited by the claims, the scope is not limited by such examples or exemplary terms.

Hereinbelow, a capacitor according to at least some embodiments, an electronic device including the same, and a method of preparing a capacitor will be described in greater detail.

A capacitor according to at least one embodiment may include a first electrode; a second electrode opposite to the first electrode; and a dielectric layer between the first electrode and the second electrode. The dielectric layer may include an insertion layer disposed within the dielectric layer. The insertion layer may include an impurity and an aluminum oxide. The impurity may include a nonmetal element belonging to Group 1 or Group 17 in the Periodic Table of the Elements. The content of the impurity may be greater than 0 at % and less than 1 at %, as a ratio of the number of atoms of the impurity to the total number of atoms of the impurity and metal in the insertion layer. By including a dielectric layer in the capacitor and incorporating an impurity and an aluminum oxide into the dielectric layer, leakage current along the grain boundaries may be effectively blocked, while suppressing a decrease in the dielectric constant of the dielectric layer. By selectively introducing an aluminum oxide onto the grain boundaries of the dielectric layer, the capacitor may effectively block leakage current flowing along the grain boundaries while suppressing a decrease in the dielectric constant of the dielectric layer.

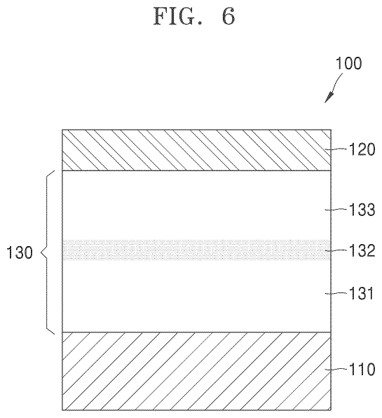

FIG. 6 is a cross-sectional view showing a schematic structure of a capacitor according to at least one embodiment. Referring to FIG. 6, a capacitor 100 according to at least one embodiment may include a first electrode 110; a second electrode 120 opposing the first electrode 110; and a dielectric layer 130 between the first electrode 110 and the second electrode 120. The dielectric layer 130 may include an insertion layer 132 disposed within the dielectric layer 130. The insertion layer 132 may include an impurity and an aluminum oxide. The impurity may include a nonmetal element belonging to Group 1 or Group 17 in the Periodic Table of the Elements.

The content of the impurity, as the ratio of the number of atoms of the impurity to the total number of atoms of the impurity and metal in the insertion layer 132, may be, for example, greater than 0 at % and less than 1 at %, greater than 0 at % and 0.5 at % or less, greater than 0 at % and 0.3 at % or less, greater than 0 at % and 0.1 at % or less, greater than 0 at % and 0.05 at % or less, greater than 0 at % and 0.03 at % or less, greater than 0 at % and 0.01 at % or less, greater than 0 at % and 0.005 at % or less, or greater than 0 at % and 0.001 at % or less. The metal atoms in the insertion layer 132 may include aluminum and all other metal atoms besides aluminum that are distributed within the insertion layer 132.

The insertion layer 132 may include an impurity, and the impurity may include, for example, hydrogen, fluorine, chlorine, bromine, and/or a combination thereof. By including such impurities, the insertion layer 132 may suppress a decrease in the dielectric constant and leakage current of the capacitor 100.

The insertion layer 132 may include an aluminum oxide, and the aluminum oxide may include AlₐO_{b} wherein 1.0≤a≤3.0 and 2.0≤b≤4.0 may be satisfied. By including such an aluminum oxide, the insertion layer 132 may suppress a decrease in the dielectric constant and leakage current of the capacitor 100.

The insertion layer 132 may further include, for example, a dielectric material in addition to the impurity and the aluminum oxide. The dielectric material may include, for example, a first metal oxide. The dielectric material may include a first metal oxide having a tetragonal (and/or similar crystal) structure and a dielectric constant of 20 or more and 70 or less. The first metal oxide may include, for example, at least one first metal belonging to Groups 2 to 12 in the Periodic Table of the Elements. The first metal may include, for example, titanium (Ti), hafnium (Hf), zirconium (Zr), silicon (Si), lanthanum (La), gadolinium (Gd), strontium (Sr), yttrium (Y), niobium (Nb), tantalum (Ta), chromium (Cr), copper (Cu), iron (Fc), magnesium (Mg), nickel (Ni), scandium (Sc), germanium (Ge), cerium (Ce), praseodymium (Pr), neodymium (Nd), samarium (Sm), europium (Eu), dysprosium (Dy), holmium (Ho), erbium (Er), thulium (Tm), ytterbium (Yb), lutetium (Lu), and/or a combination thereof. The first metal oxide may include M_{c}O_{d} wherein 1.0≤c≤3.0 and 2.0≤d<5.0 may be satisfied, wherein M may include titanium (Ti), hafnium (Hf), zirconium (Zr), silicon (Si), lanthanum (La), gadolinium (Gd), strontium (Sr), yttrium (Y), niobium (Nb), tantalum (Ta), chromium (Cr), copper (Cu), iron (Fc), magnesium (Mg), nickel (Ni), scandium (Sc), germanium (Ge), and/or a combination thereof. The first metal oxide may include, for example, ZrO₂, HfO₂, ZrₓHf_{y}O₂ (0<x<1, 0<y<1), TiO₂, SiO₂, La₂O₃, GdO₂, SrO₂, Y₂O₃, La₂O₃, Nb₂O₅, Ta₂O₅, Cr₂O₃, CuO, Fe₂O₃, MgO, Nb₂O₅, NiO, Ta₂O₅, Sc₂O₃, CeO₂, PrOₓ (1≤x≤5), Nd₂O₃, Sm₂O₃, EuO_{y} (1≤y≤5), Gd₂O₃, Dy₂O₃, Ho₂O₃, Er₂O₃, Tm₂O₃, Yb₂O₃, Lu₂O₃, and/or a combination thereof. By including such first metal oxide dielectric material in the insertion layer 132, a decrease in dielectric constant and leakage current of the capacitor 100 may be suppressed and/or prevented.

The insertion layer 132 may include, for example, an aluminum oxide and a first metal oxide. The insertion layer 132 may include aluminum and a first metal, wherein the content of the first metal of the metal oxide may be higher than the content of the aluminum of the aluminum oxide in the insertion layer 132. In the insertion layer 132, the content of the first metal may be a ratio of the number of atoms of the first metal to the total number of atoms of the aluminum and the first metal. In the insertion layer 132, the content of the aluminum may be 10 at % or less, 5 at % or less, 3 at % or less, or 1 at % or less as the ratio of the number of atoms of the aluminum to the total number of atoms of the aluminum and the first metal. By having such an aluminum content, the insertion layer 132 may suppress a decrease in the dielectric constant and leakage current of the capacitor 100.

The insertion layer 132 may include, for example, AlₐM_{b}O₃, wherein 0<a<1 and 0<b<2 may be satisfied, and M may be a metal belonging to Groups 2 to 12 in the Periodic Table of the Elements. In the insertion layer 132, the ratio of aluminum (a) to M (b) may satisfy 0<a/b≤0.1. The insertion layer 132 may include, for example, Al_{c}Zr_{d}O₃, Al_{c}Hf_{d}O₃, Al_{c}Zr_{d}HfₑO₃, Al_{c}Ti_{d}O₃, Al_{c}Zr_{d}TiₑO₃, Al_{c}Hf_{d}TiₑO₃, and/or a combination thereof, wherein 0<c<1, 0<d<2, and 0<e<2 may be satisfied. By including an aluminum-first metal oxide represented as AlₐM_{b}O₃ in the insertion layer 132, it is possible to suppress the decrease in dielectric constant and leakage current of the capacitor 100.

The dielectric layer 130 may further include a first dielectric material layer 131 adjacent to the first electrode 110 and a second dielectric material layer 133 adjacent to the second electrode 120. The insertion layer 132 may be disposed between the first dielectric material layer 131 and the second dielectric material layer 133. That is, the dielectric layer 130 may have a structure in which the insertion layer 132 is additionally disposed within one dielectric material.

The first dielectric material layer 131 and the second dielectric material layer 133 may include the same dielectric material. The dielectric materials included in the first dielectric material layer 131 and the second dielectric material layer 133 may be selected from the dielectric materials used in the insertion layer 132 described above.

For example, the first dielectric material layer 131 and the second dielectric material layer 133 may include the same dielectric material as the insertion layer 132. The dielectric materials included in the first dielectric material layer 131 and the second dielectric material layer 133 may be selected to be the same material as the dielectric material (e.g., the first metal oxide) used in the insertion layer 132 described above.

By including the same dielectric material as the insertion layer 132 in the first dielectric material layer 131 and the second dielectric material layer 133, it is possible to suppress the decrease in dielectric constant and leakage current of the capacitor 100.

A thickness of the dielectric layer may be, for example, about 10 nm or less. A thickness of the dielectric layer may be, for example, about 3 nm to about 10 nm.

A thickness of the insertion layer may be, for example, about 5 nm or less, about 3 nm or less, or about 1 nm or less. A thickness of the insertion layer may be, for example, about 0.1 nm to about 5 nm, about 0.1 nm to about 3 nm, or about 0.1 nm to about 1 nm.

The first electrode 110 may be disposed on a substrate (not shown). The substrate may be part of a structure that supports the capacitor or may be part of a device connected to the capacitor. The substrate may include a semiconductor material pattern, an insulating material pattern, and/or a conductive material pattern. The substrate may include, for example, a semiconductor material such as silicon (Si), germanium (Ge), silicon germanium (SiGe), silicon carbide (SiC), gallium arsenide (GaAs), indium arsenide (InAs), indium phosphide (InP), and/or may include an insulating material such as silicon oxide, silicon nitride, or silicon oxynitride.

The second electrode 120 may be disposed to oppose the first electrode 110 with a space therebetween. The first electrode 110 and the second electrode 120 may each include a metal, a metal nitride, a metal oxide, or a combination thereof. For example, the first electrode and the second electrode each independently may include at least one conductive metal selected from titanium (Ti), nickel (Ni), aluminum (Al), tantalum (Ta), tungsten (W), platinum (Pt), palladium (Pd), gold (Au), iridium (Ir), rhodium (Rh), molybdenum (Mo), vanadium (V), niobium (Nb), ruthenium (Ru), and/or cobalt (Co), a conductive metal oxide of any one of the aforementioned metals, and/or a conductive metal nitride of any one of the aforementioned metals. The conductive metal oxide may include, for example, platinum oxide (PtO), iridium oxide (IrO₂), ruthenium oxide (RuO₂), strontium ruthenium oxide (SrRuO₃), barium strontium ruthenium oxide ((Ba,Sr)RuO₃), calcium ruthenium oxide (CaRuO₃), or lanthanum strontium cobalt oxide ((La,Sr)CoO₃). The conductive metal nitride may include, for example, titanium nitride (TiN), tantalum nitride (TaN), niobium nitride (NbN), molybdenum nitride (MoN), cobalt nitride (CON), or tungsten nitride (WN).

The first electrode 110 and the second electrode 120 may each independently have a single-layer structure or a stacked structure of a plurality of material layers. The first electrode 110 and the second electrode 120 may each independently include, for example, a single layer of titanium nitride (TiN) or a single layer of niobium nitride (NbN). The first electrode 110 and the second electrode 120 may each independently have, for example, a stacked structure in which titanium nitride (TiN) and niobium nitride (NbN) are alternately stacked at least once.

The first electrode 110 and the second electrode 120 may each independently include, for example, a metal nitride represented by MM′N. M is a metal element, M′ is an element different from M, and N is nitrogen. Such metal nitrides may also include an MN metal nitride doped with the element M′. M may be one or more elements selected from H, Li, As, Se, N, O, P, S, Be, B, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Rc, Os, Ir, Pt, Au, Hg, TI, Pb, Bi, Po, Fr, Ra, Ac, Th, Pa, and U. M′ may be one or more elements selected from H, Li, As, Se, N, O, P, S, Be, B, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, Bi, Po, Fr, Ra, Ac, Th, Pa, and U. In the metal nitride MM′N where the composition ratio of M, M′, and N is denoted as x:y:z, 0≤x≤2, 0≤y≤2, and 0<z≤4 may be satisfied, wherein one of x or y may not be 0.

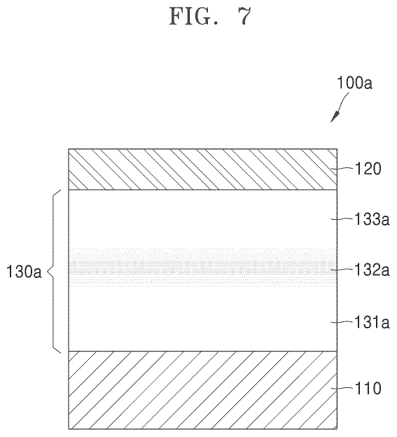

FIG. 7 is a cross-sectional view showing the schematic structure of a capacitor according to at least one embodiment. Referring to FIG. 7, a capacitor 100a according to at least one embodiment may include a first electrode 110; a second electrode 120 opposing the first electrode 110; and a dielectric layer 130a between the first electrode 110 and the second electrode 120, wherein the dielectric layer 130a may include a first dielectric material layer 131a, an insertion layer 132a, and a second dielectric material layer 133a. Compared to the capacitor 100 of FIG. 6, in the dielectric layer 130a of the capacitor 100a of FIG. 7, the composition of material may continuously vary at the boundary region between the first dielectric material layer 131a and the insertion layer 132a, and at the boundary region between the second dielectric material layer 133a and the insertion layer 132a. For example, the composition ratio of aluminum may continuously vary along the first dielectric material layer 131a, the insertion layer 132a, and the second dielectric material layer 133a, and a peak in the composition ratio of aluminum (Al) may be formed within the insertion layer 132a. In addition, a material of the first and second dielectric material layers 131a and 133a may also be distributed within the insertion layer 132a.

The insertion layer 132a may include, for example, an impurity, an aluminum oxide, and a first metal oxide. The aluminum content within the insertion layer 132a may be higher than the aluminum content at the boundary region between the first dielectric material layer 131a and the insertion layer 132a. The aluminum content within the insertion layer 132a may be higher than the aluminum content at the boundary region between the second dielectric material layer 133a and the insertion layer 132a. Due to the aluminum content within the insertion layer 132a being higher than the aluminum content at the boundary region between the first dielectric material layer 131a and the insertion layer 132a and/or the boundary region between the second dielectric material layer 133a and the insertion layer 132a, a decrease in the dielectric constant and a leakage current of the capacitor 100a may be suppressed. The aluminum content may be a ratio of the number of aluminum atoms to the total number of atoms of aluminum and the first metal. The aluminum content may be expressed, for example, in at %.

The dielectric layer 130, 130a may include a crystalline dielectric material. Due to the dielectric layer 130, 130a including a crystalline dielectric material, aluminum oxide may be more easily selectively disposed on the grain boundaries of the crystalline dielectric material. Due to the dielectric layer 130, 130a including a crystalline dielectric material, a decrease in the dielectric constant and a leakage current of the capacitors 100, 100a may be suppressed. Because the dielectric layer 130, 130a can suppress the decrease in the dielectric constant and leakage current of the capacitors 100, 100a, the dielectric layer 130, 130a may have a reduced thickness, allowing the capacitors 100, 100a to be further miniaturized.

An electronic device according to at least one embodiment may include a transistor; and a capacitor electrically connected to the transistor. The capacitor may include a first electrode; a second electrode opposing the first electrode; and a dielectric layer between the first electrode and the second electrode, wherein the dielectric layer may include an insertion layer disposed within the dielectric layer. The insertion layer may include an impurity, and the impurity may include a nonmetal element belonging to Group 1 or Group 17 of the Periodic Table of the Elements. The content of the impurity may be greater than 0 at % and less than 1 at %, as a ratio of the number of impurity atoms to the total number of impurity and metal atoms in the insertion layer.

The capacitor may be employed in various electronic devices. The capacitor may be utilized as a DRAM component together with a transistor. In addition, the capacitor may form part of an electronic circuit that constitutes an electronic device along with other circuit elements.

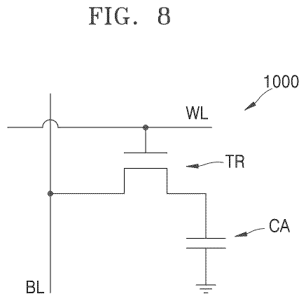

FIG. 8 is a circuit diagram illustrating the schematic circuit configuration and operation of an electronic device employing a capacitor according to embodiments.

The circuit diagram of the electronic device 1000 pertains to a single cell of a dynamic random-access memory (DRAM) device and includes one transistor TR, one capacitor CA, a word line WL, and a bit line BL. The capacitor CA may be the capacitor 100 or 100a described in FIGS. 6 to 7.

The method of writing data to a DRAM may be as follows. First, after applying a gate voltage (high) to the gate electrode through the word line WL to turn the transistor TR ‘ON’, the data voltage value to be input to the bit line BL-VDD (hereinafter referred to as “high voltage”) or 0 (hereinafter referred to as “low voltage”)—is applied. When a high voltage is applied to both the word line and the bit line, the capacitor CA charges and data “1” is recorded. When a high voltage is applied to the word line and a low voltage to the bit line, the capacitor CA discharges and data “0” is recorded.

To read data, after applying a high voltage to the word line WL to turn on the transistor TR of the DRAM, a voltage of VDD/2 is applied to the bit line BL. If the data in the DRAM is “1”—that is, if the capacitor CA voltage is VDD—the charges in the capacitor CA slowly move to the bit line BL, causing the voltage of the bit line BL to become slightly higher than VDD/2. Conversely, if the data in the capacitor CA is “0”, the charges in the bit line BL move to the capacitor CA, making the voltage of the bit line BL slightly lower than VDD/2. The potential difference thus generated in the bit line may be detected by a sense amplifier, which amplifies the value to determine whether the data is “0” or “1”.

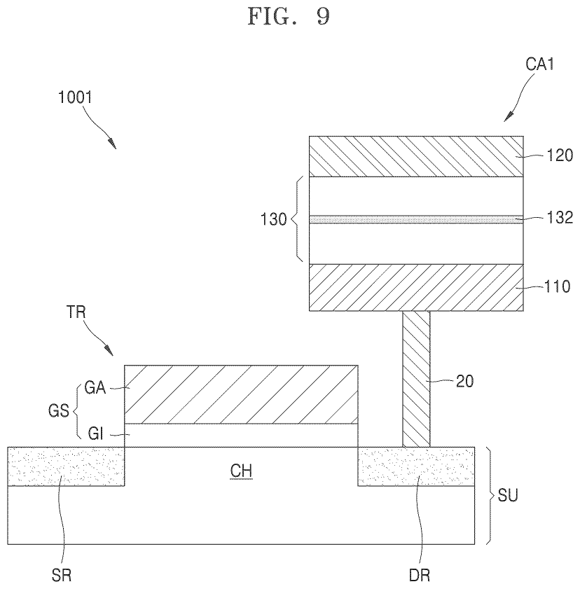

FIG. 9 is a schematic diagram illustrating an electronic device according to at least one embodiment.

Referring to FIG. 9, an electronic device 1001 may include a structure in which a capacitor CA1 and a transistor TR are electrically connected by a contact 20. The capacitor CA1 may include a first electrode 110, a second electrode 120 opposing the first electrode 110, a dielectric layer 130 between the first electrode 110 and the second electrode 120, and an insertion layer 132 disposed within the dielectric layer 130. The insertion layer 132 may include an impurity, and the impurity may include a nonmetal element belonging to Group 1 or Group 17 in the Periodic Table of the Elements of the Elements, wherein the impurity content may be more than 0 at % and less than 1 at %, as the ratio of the number of impurity atoms to the total number of impurity and metal atoms in the insertion layer 132. The capacitor CA1 may be the capacitor 100 or 100a as described in FIGS. 6 to 7, and since this has been previously described, a detailed explanation thereof will be omitted.

The transistor TR may be a field effect transistor. The transistor TR includes a semiconductor substrate SU having a source region SR, a drain region DR, and a channel region CH, and a gate stack GS disposed on the semiconductor substrate SU to oppose the channel region CH, the gate stack including a gate insulating layer GI and a gate electrode GA.

The channel region CH may be a region between the source region SR and the drain region DR, and may be electrically connected to the source region SR and the drain region DR. The source region SR may be electrically connected to or in contact with one end of the channel region CH, and the drain region DR may be electrically connected to or in contact with the other end of the channel region CH. The channel region CH may be defined as the substrate region between the source region SR and the drain region DR within the semiconductor substrate SU.

The semiconductor substrate SU may include a semiconductor material. The semiconductor substrate SU may include, for example, semiconductor materials such as silicon (Si), germanium (Ge), silicon germanium (SiGe), silicon carbide (SiC), gallium arsenide (GaAs), indium arsenide (InAs), indium phosphide (InP), and/or the like. Additionally, the semiconductor substrate SU may also include a silicon on insulator (SOI) substrate.

The source region SR, the drain region DR, and the channel region CH may each independently be formed by implanting an impurity into different regions of the semiconductor substrate SU, and in this case, the source region SR, the channel region CH, and the drain region DR may include the substrate material as a base material. The source region SR and the drain region DR may be formed of a conductive material, in which case, for example, the source region SR and the drain region DR may include a metal, a metal compound, or a conductive polymer.

The channel region CH, unlike what is illustrated, may be implemented as a separate material layer (thin film). In this case, for example, the channel region CH may include at least one of an elemental semiconductor (e.g., Si, Ge, SiGe, etc.) a compound semiconductor (e.g., a group III-V semiconductor), an oxide semiconductor, a nitride semiconductor, an oxynitride semiconductor, a two-dimensional material (2D material), quantum dots, an organic semiconductor, and/or the like. For example, the oxide semiconductor may include InGaZnO, the 2D material may include transition metal dichalcogenide (TMD) or graphene, and the quantum dots may include colloidal quantum dots (colloidal QD) or nanocrystal structures.

The gate electrode GA may be disposed on the semiconductor substrate SU, spaced apart from the semiconductor substrate SU, so as to oppose the channel region CH. The gate electrode GA may include at least one of metal, metal nitride, metal carbide, and polysilicon. For example, the metal may include at least one of aluminum (Al), tungsten (W), molybdenum (Mo), titanium (Ti), and tantalum (Ta), and the metal nitride film may include at least one of a titanium nitride film (TiN film) and a tantalum nitride film (TaN film). The metal carbide may include at least one of metal carbides doped with (or containing) aluminum and silicon, and specific examples may include TiAlC, TaAlC, TiSiC, or TaSiC.

The gate electrode GA may have a stacked structure of a plurality of materials and may have, for example, a stacked structure of a metal nitride layer/metal layer such as TiN/Al, or a stacked structure of a metal nitride layer/metal carbide layer/metal layer such as TiN/TiAlC/W. However, the materials mentioned above are merely exemplary.

A gate insulating layer GI may be further disposed between the semiconductor substrate SU and the gate electrode GA. The gate insulating layer GI may include a paraelectric material or a high-k dielectric material and may have a dielectric constant of approximately 20 to 70.

The gate insulating layer GI may include an insulator, such as least one of silicon oxide, silicon nitride, aluminum oxide, hafnium oxide, zirconium oxide, a two-dimensional insulator (2D insulator) such as h-BN (hexagonal boron nitride), and/or the like. For example, the gate insulating layer GI may include silicon oxide (SiO₂), silicon nitride (SiNₓ), etc., and may also include hafnium oxide (HfO₂), hafnium silicon oxide (HfSiO₄), lanthanum oxide (La₂O₃), lanthanum aluminum oxide (LaAlO₃), zirconium oxide (ZrO₂), hafnium zirconium oxide (HfZrO₂), zirconium silicon oxide (ZrSiO₄), tantalum oxide (Ta₂O₅), titanium oxide (TiO₂), strontium titanium oxide (SrTiO₃), yttrium oxide (Y₂O₃), aluminum oxide (Al₂O₃), lead scandium tantalum oxide (PbSc_{0.5}Ta_{0.5}O₃), lead zinc niobate (PbZnNbO₃), etc. Additionally, the gate insulating layer GI may include metal oxynitrides such as aluminum oxynitride (AlON), zirconium oxynitride (ZrON), hafnium oxynitride (HfON), lanthanum oxynitride (LaON), yttrium oxynitride (YON); silicates such as ZrSiON, HfSiON, YSiON, LaSiON; or aluminates such as ZrAlON, HfAlON. The gate insulating layer GI may form a gate stack together with the gate electrode GA.

One of the electrodes 110 or 120 of the capacitor CA1 may be electrically connected to one of the source region SR or drain region DR of the transistor TR via a contact 20. Here, the contact 20 may include an appropriate conductive material, for example, tungsten, copper, aluminum, polysilicon, etc. The other of the electrodes 110 or 120 of the capacitor CA1 may be electrically connected to a ground.

The arrangement of the capacitor CA1 and the transistor TR may be variously modified. For example, the capacitor CA1 may be disposed on the semiconductor substrate SU, or may have a structure embedded within the semiconductor substrate SU.

FIG. 9 illustrates an electronic device 1001 that includes one capacitor CA1 and one transistor TR; however, this is only an example, and the electronic device 1001 may include a plurality of capacitors and a plurality of transistors.

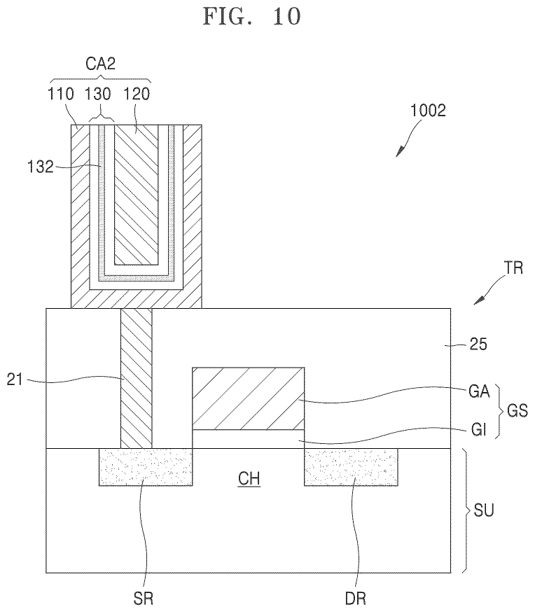

FIG. 10 illustrates an electronic device according to at least one embodiment.

Referring to FIG. 10, the electronic device 1002 may include a structure in which the capacitor CA2 and the transistor TR are electrically connected by a contact 21. The transistor TR includes a semiconductor substrate SU having a source region SR, a drain region DR, and a channel region CH, and a gate stack GS disposed on the semiconductor substrate SU to oppose the channel region CH, the gate stack including a gate insulating film 25 and a gate electrode GA.

The interlayer insulating film 25 may be provided in a form covering the gate stack GS on the semiconductor substrate SU. The interlayer insulating film 25 may include an insulating material. For example, the interlayer insulating film 25 may include silicon oxide such as SiO₂, aluminum oxide such as Al₂O₃, or a high-k dielectric material such as HfO₂. The contact 21 may penetrate the interlayer insulating film 25 to electrically connect the transistor TR and the capacitor CA1.

The capacitor CA1 may include a first electrode 110, a second electrode 120 opposing the first electrode 110, a dielectric layer 130 between the first electrode 110 and the second electrode 120, and an insertion layer 132 disposed within the dielectric layer 130. The insertion layer 132 may include an impurity, and the impurity may include a nonmetal element belonging to Group 1 or Group 17 in the Periodic Table of the Elements of the Elements, wherein the impurity content may be more than 0 at % and less than 1 at %, as the ratio of the number of impurity atoms to the total number of impurity and metal atoms in the insertion layer 132. The first electrode 110 and the second electrode 120 are presented in shapes that can maximize the contact area with the dielectric layer 130, and the material of the capacitor CA2 may be substantially the same as that of the capacitors 100, 100a described in FIGS. 6 to 7.

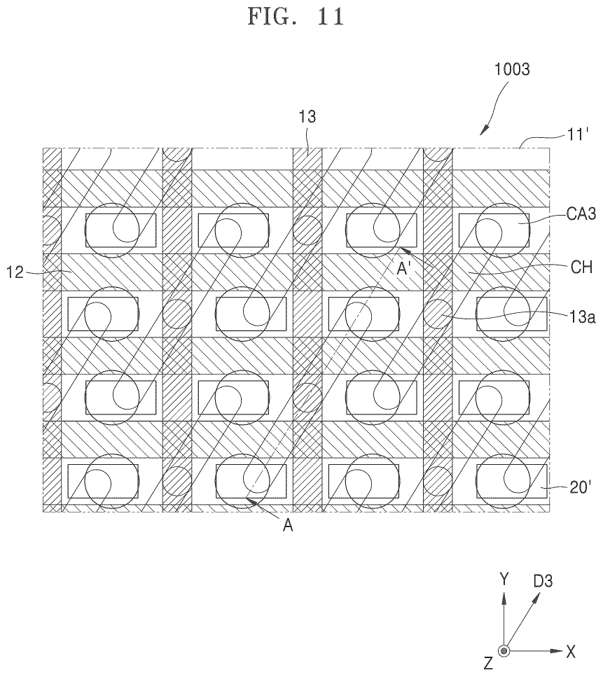

FIG. 11 is a plan view illustrating an electronic device according to at least one embodiment.

Referring to FIG. 11, an electronic device 1003 may include a structure in which a plurality of capacitors and a plurality of field-effect transistors are repeatedly arranged. The electronic device 1003 may include a field-effect transistor including a semiconductor substrate 11′ including a source, a drain, and a channel, and a gate stack 12; a contact structure 20′ disposed on the semiconductor substrate 11′ so as not to overlap with the gate stack 12; and a capacitor CA3 disposed on the contact structure 20′, and may further include a bit line structure 13 that electrically connects a plurality of field-effect transistors.

FIG. 11 illustratively shows a form in which both the contact structures 20′ and the capacitors CA3 are repeatedly arranged along the X and Y directions, but the present disclosure is not limited thereto. For example, the contact structures 20′ may be arranged along the X and Y directions, and the capacitors CA3 may be arranged in a hexagonal shape (e.g., like a honeycomb structure).

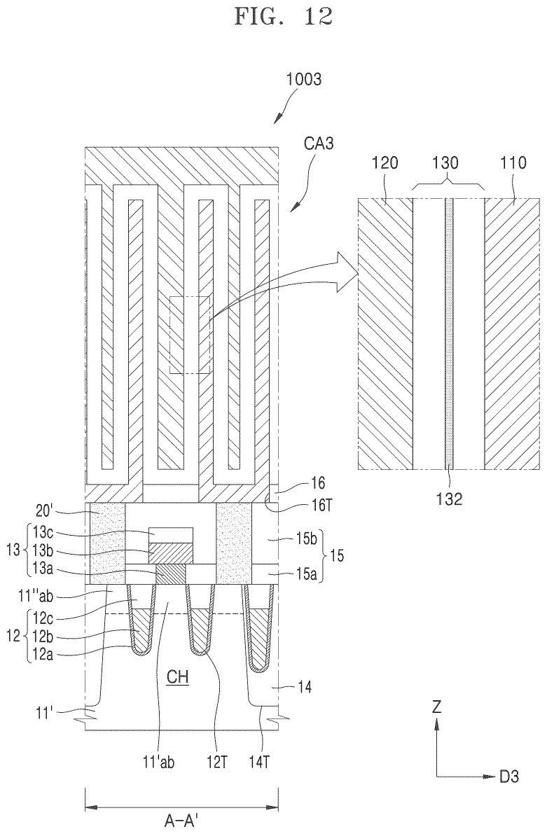

FIG. 12 is a cross-sectional view taken along line A-A′ of FIG. 11.

Referring to FIG. 12, the semiconductor substrate 11′ may have a shallow trench isolation (STI) structure that includes a device isolation film 14. The device isolation film 14 may be a single layer made of one type of insulating film or may be a multilayer composed of a combination of two or more types of insulating films. The device isolation film 14 may include a device isolation trench 14T within the semiconductor substrate 11′, and the device isolation trench 14T may be filled with an insulating material. The insulating material may include at least one of fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), and tonen silazane (TOSZ), but is not limited thereto.

The semiconductor substrate 11′ may include a channel region CH defined by a device isolation film 14, and may further include a gate line trench 12T disposed to extend along the X-direction, parallel to the upper surface of the semiconductor substrate 11′. The channel region CH may have a relatively long island shape with a short axis and a long axis. The long axis of the channel region CH may be arranged along the D3 direction parallel to the upper surface of the semiconductor substrate 11′, as illustratively shown in FIG. 12.

The gate line trench 12T may be disposed to cross the channel region CH at a predetermined depth from the upper surface of the semiconductor substrate 11′, or may be disposed within the channel region CH. The gate line trench 12T may also be disposed within the device isolation trench 14T, and the gate line trench 12T within the device isolation trench 14T may have a lower bottom surface than the gate line trench 12T of the channel region CH. The first source/drain 11′ab and the second source/drain 11″ab may be disposed on the upper portion of the channel region CH located on both sides of the gate line trench 12T.

A gate stack 12 may be disposed inside the gate line trench 12T. For example, a gate insulating layer 12a, a gate electrode 12b, and a gate capping layer 12c may be sequentially disposed inside the gate line trench 12T. For the gate insulating layer 12a and the gate electrode 12b, see the above description. The gate capping layer 12c may include at least one of silicon oxide, silicon oxynitride, and silicon nitride. The gate capping layer 12c may be disposed on the gate electrode GA to fill the remaining portion of the gate line trench 12T.

A bit line structure 13 may be disposed on the first source/drain 1l′ab. The bit line structure 13 may be arranged to extend in the Y-direction parallel to the upper surface of the semiconductor substrate 11′. The bit line structure 13 may be electrically connected to the first source/drain 11′ab and may sequentially include, on the substrate, a bit line contact 13a, a bit line 13b, and a bit line capping layer 13c. For example, the bit line contact 13a may include polysilicon, the bit line 13b may include a metal material, and the bit line capping layer 13c may include an insulating material such as silicon nitride or silicon oxynitride, etc.

FIG. 12 illustrates a case in which the bit line contact 13a has a bottom surface at the same level as the upper surface of the semiconductor substrate 11′, but this is merely exemplary and not limiting. For example, in at least one embodiment, a recess formed to a predetermined depth from the upper surface of the semiconductor substrate 11′ may be further provided, and the bit line contact 13a may extend into the recess so that the bottom surface of the bit line contact 13a is formed lower than the upper surface of the semiconductor substrate 11′.

The bit line structure 13 may further include a bit line interlayer (not shown) between the bit line contact 13a and the bit line 13b. The bit line interlayer may include a metal silicide such as tungsten silicide or a metal nitride such as tungsten nitride. Additionally, a bit line spacer (not shown) may be further formed on a sidewall of the bit line structure 13. The bit line spacer may have a single-layer structure or a multilayer structure and may include an insulating material such as silicon oxide, silicon oxynitride, or silicon nitride. Furthermore, the bit line spacer may further include an air space (not shown).

A contact structure 20′ may be disposed on the second source/drain 11″ab. The contact structure 20′ and the bit line structure 13 may be disposed on different source/drains on the substrate. The contact structure 20′ may have a structure in which a lower contact pattern (not shown), a metal silicide layer (not shown), and an upper contact pattern (not shown) are sequentially stacked on the second source/drain 11″ab. The contact structure 20′ may further include a barrier layer (not shown) that surrounds the side and bottom surfaces of the upper contact pattern. For example, the lower contact pattern may include a polysilicon, the upper contact pattern may include a metal material, and the barrier layer may include a conductive metal nitride.

A capacitor CA3 may be electrically connected to the contact structure 20′ and disposed on the semiconductor substrate 11′. For example, the capacitor CA3 may include a first electrode 110 electrically connected to the contact structure 20′, a second electrode 120 disposed apart from the first electrode 110, a dielectric layer 130 disposed between the first electrode 110 and the second electrode 120, and an insertion layer 132 provided within the dielectric layer 130. The insertion layer 132 may include an impurity, and the impurity may include a nonmetal element belonging to Group 1 or Group 17 in the Periodic Table of the Elements of the Elements, wherein the impurity content may be more than 0 at % and less than 1 at %, as the ratio of the number of impurity atoms to the total number of impurity and metal atoms in the insertion layer 132. The first electrode 110 may have a cylindrical or cup shape with an internal space that is closed at the bottom. The second electrode 120 may have a comb shape with tines extending into the internal space formed by the first electrode 110 and into the regions between adjacent first electrodes 110. The dielectric layer 130 may be disposed between the first electrode 110 and the second electrode 120, arranged parallel to their surfaces. Since the materials of the first electrode 110, the second electrode 120, the dielectric layer 130, and the insertion layer 132 constituting the capacitor CA3 are the same as and/or substantially similar to those of the aforementioned capacitors 100 and 100a with reference to FIGS. 6 to 7, and therefore the descriptions thereof are omitted.

An interlayer insulating film 15 may be further disposed between the capacitor CA3 and the semiconductor substrate 11′. The interlayer insulating film 15 may be arranged in the space between the capacitor CA3 and the semiconductor substrate 11′ where other structures are not present. For example, the interlayer insulating film 15 may be disposed to cover wiring and/or electrode structures such as the bit line structures 13, contact structures 20′, and gate stack 12 on the substrate. For example, the interlayer insulating film 15 may surround the walls of the contact structure 20′. The interlayer insulating film 15 may include a first interlayer insulating film 15a that surrounds the bit line contact 13a, and a second interlayer insulating film 15b that covers the sides and/or upper surfaces of the bit line 13b and the bit line capping layer 13c.

The second electrode 120 of the capacitor CA3 may be disposed on the interlayer insulating film 15, specifically on the second interlayer insulating film 15b. In addition, when multiple capacitors CA3 are arranged, the bottom surfaces of the plurality of second electrodes 120 may be separated by an etch stop layer 16. That is, the etch stop layer 16 may include openings 16T, and the bottom surfaces of the second electrodes 120 of the capacitors CA3 may be disposed within these openings 16T. As shown, the second electrode 120 may have a cylindrical or cup shape with an internal space that is closed at the bottom. The capacitor CA3 may further include a support part (not shown) to prevent tilting or collapsing of the second electrode 120, and the support part may be disposed on the sidewalls of the second electrode 120.

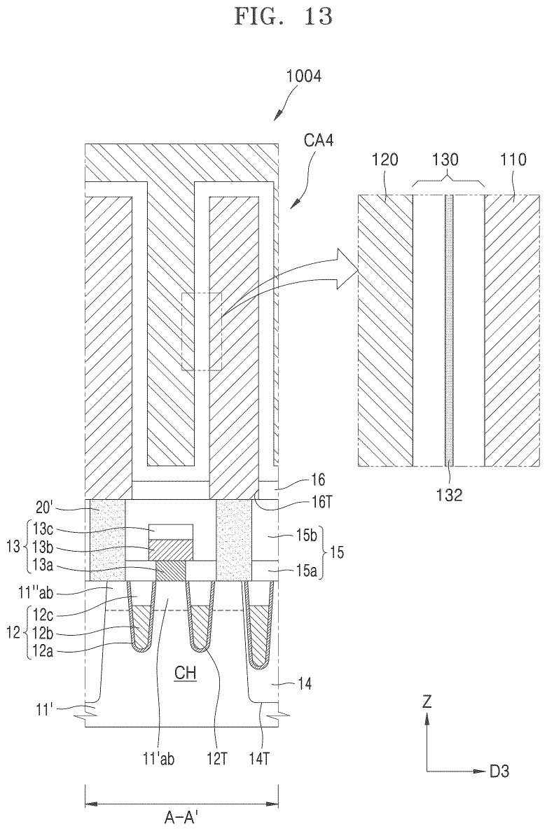

FIG. 13 is a cross-sectional view illustrating an electronic device according to at least one embodiment.

The electronic device 1004 of this embodiment is illustrated in a cross-sectional view corresponding to the A-A′ sectional view of FIG. 11, and differs from FIG. 12 only in the shape of the capacitor CA4. The capacitor CA4 is electrically connected to the contact structure 20′ and disposed on the semiconductor substrate 11′ and includes a first electrode 110 electrically connected to the contact structure 20′, a second electrode 120 disposed apart from the first electrode 110, a dielectric layer 130 disposed between the first electrode 110 and the second electrode 120, and an insertion layer 132 provided within the dielectric layer 130. The insertion layer 132 may include an impurity, and the impurity may include a nonmetal element belonging to Group 1 or Group 17 in the Periodic Table of the Elements of the Elements, wherein the impurity content may be more than 0 at % and less than 1 at %, as the ratio of the number of atoms of the impurity to the total number of atoms of the impurity and metal in the insertion layer 132. The materials of the first electrode 110, the second electrode 120, the dielectric layer 130, and the insertion layer 132 are substantially the same as those of the aforementioned capacitors 100 and 100a with reference to FIGS. 6 to 7.

The first electrode 110 may have a pillar shape such as a cylinder, rectangular prism, or polygonal prism extending along the vertical direction (Z direction). The second electrode 120 may have a comb shape with tines extending into the regions between adjacent first electrodes 110. The dielectric layer 130 may be disposed between the first electrode 110 and the second electrode 120, arranged parallel to their surfaces.

The capacitor and electronic device according to the embodiments described above may be applied in various applications. For example, the electronic device according to embodiments may be applied as a logic device or memory device. The electronic device according to embodiments may be used for arithmetic operations, program execution, temporary data retention, etc., in devices such as mobile devices, computers, laptops, sensors, network devices, and neuromorphic devices. In addition, the electronic components and electronic devices according to the embodiments can be useful in devices where large amounts of data are transmitted continuously.

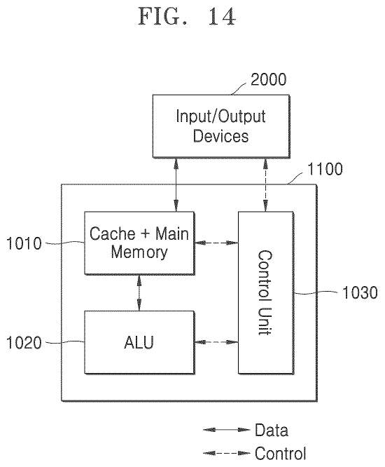

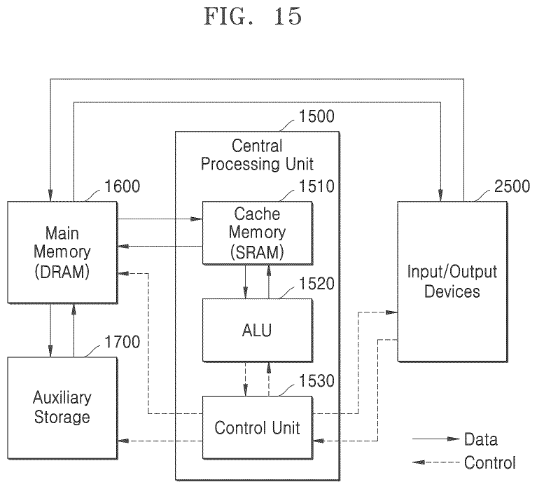

FIGS. 14 and 15 are each a conceptual diagram schematically showing a device architecture applicable to a device according to at least one embodiment.

Referring to FIG. 14, an electronic device architecture 1100 may include a memory unit 1010, an arithmetic logic unit (ALU) 1020, and a control unit 1030. The memory unit 1010, the ALU 1020, and the control unit 1030 may be electrically connected. For example, the electronic device architecture 1100 may be implemented as a single chip including the memory unit 1010, the ALU 1020, and the control unit 1030.

The memory unit 1010, the ALU 1020, and the control unit 1030 may be interconnected on-chip via metal lines to communicate directly. The memory unit 1010, the ALU 1020, and the control unit 1030 may be monolithically integrated on a single substrate to form a single chip. Input/output devices 2000 may be connected to the electronic device architecture chip 1100. Additionally, the memory unit 1010 may include both main memory and cache memory. Such an electronic device architecture (chip) 1100 may be an on-chip memory processing unit. The memory unit 1010 may include the aforementioned capacitor, and an electronic device utilizing the same. The ALU 1020 or the control unit 1030 may also each include the aforementioned capacitor.

Referring to FIG. 15, a cache memory 1510, an ALU 1520, and a control unit 1530 may constitute a central processing unit (CPU) 1500, and the cache memory 1510 may be made of static random-access memory (SRAM). Separately from the CPU 1500, a main memory 1600 and a secondary storage 1700 may be provided. The main memory 1600 may be dynamic random-access memory (DRAM) and may include the aforementioned capacitor. In some cases, the electronic device architecture may be implemented in such a way that computing unit devices and memory unit devices are adjacently arranged on a single chip without distinction between sub-units.

A method of preparing a capacitor according to at least one embodiment may include: providing a crystallized first dielectric material layer, wherein a surface of the first dielectric material layer includes a plurality of grains and grain boundaries therebetween; selectively adsorbing an impurity onto the grain boundaries; selectively adsorbing a first metal-containing inhibitor onto the plurality of grains; selectively introducing an aluminum oxide onto the grain boundaries; oxidizing the first metal-containing inhibitor to form an insertion layer; and providing a second dielectric material layer on the insertion layer, wherein the impurity includes a nonmetal element belonging to Group 1 or Group 17 in the Periodic Table of the Elements. By selectively introducing alumina on the grain boundaries on the surface of the first dielectric material layer, it is possible to effectively block leakage currents flowing along the grain boundaries of the dielectric layer while suppressing a decrease in the dielectric constant of the dielectric layer. By selectively introducing alumina on the grain boundaries of the dielectric layer, the amount of alumina used in the dielectric layer may be reduced.

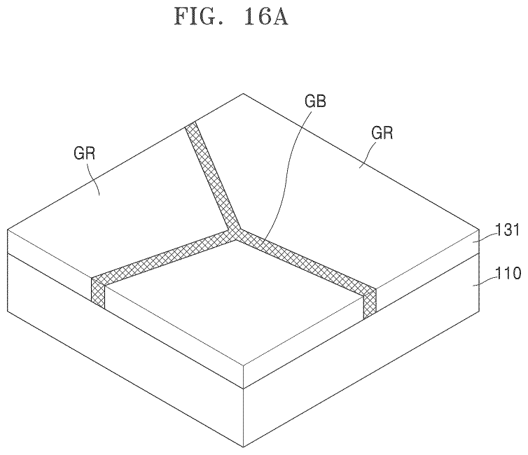

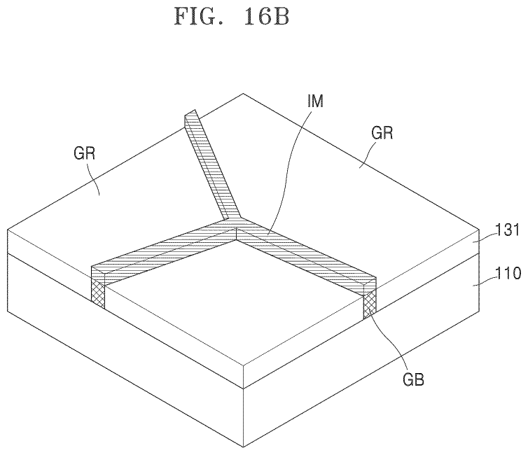

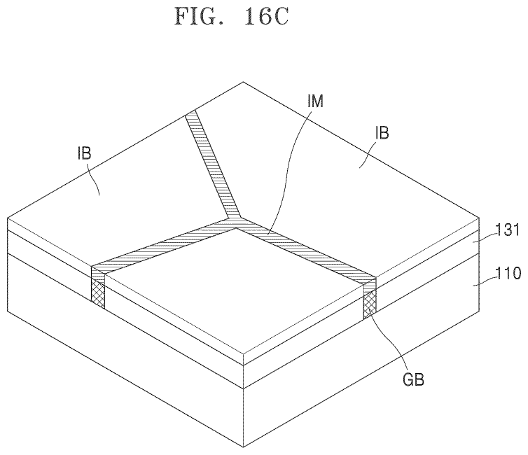

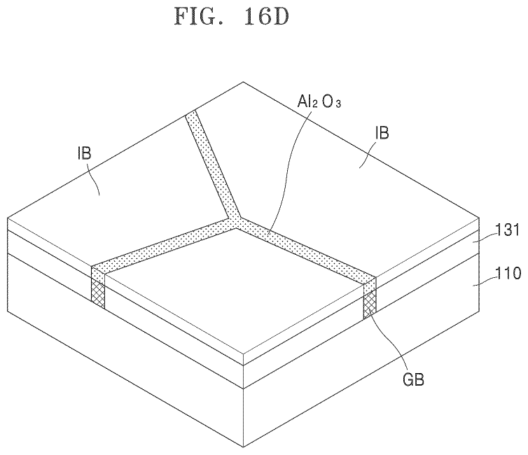

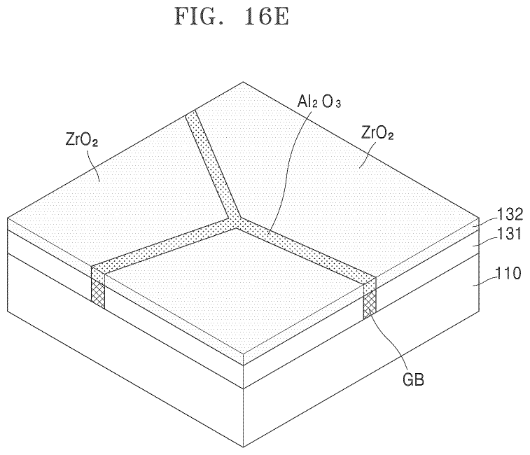

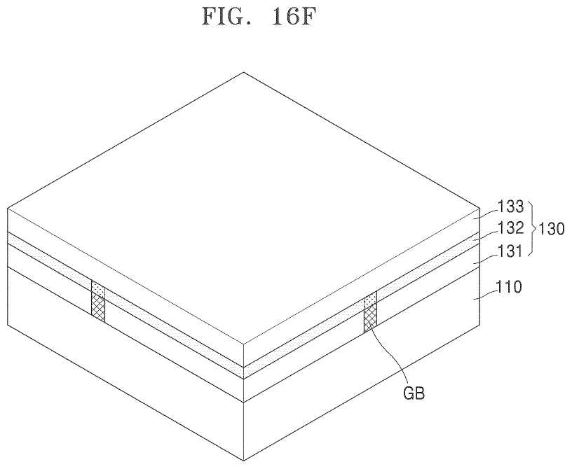

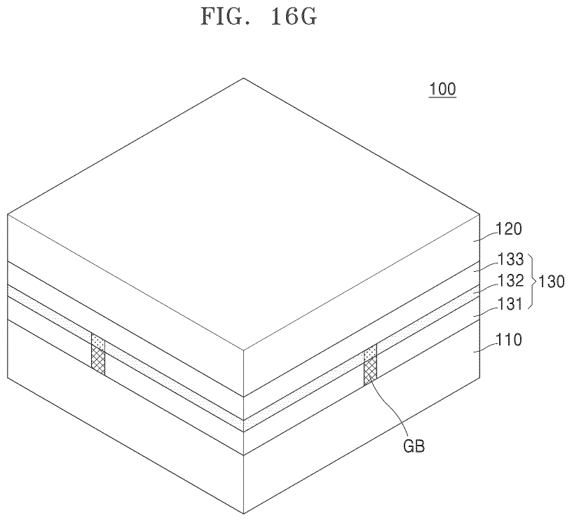

FIGS. 16A to 16E are schematic diagrams showing a method of preparing a capacitor according to at least one embodiment.

Referring to FIG. 16A, a first electrode 110 may be provided. The first electrode 110 may be disposed on a substrate (not shown). The substrate may be part of a structure that supports the capacitor or may be part of a device connected to the capacitor. For the material of the first electrode 110, refer to the capacitor described above.

The first electrode may be, for example, a titanium nitride (TiN) electrode.

A first dielectric material layer 131 may be provided on the first electrode 110. The first dielectric material layer 131 may be a crystallized layer. For example, the first dielectric material layer 131 may be grown on the first electrode 110, with grains propagating from a nucleation site, and meeting at grain boundaries. Therefore, a surface of the first dielectric material layer 131 may include a plurality of grains GR and grain boundaries GB therebetween.

The first dielectric material layer may be made of a first metal oxide. The first metal oxide may have a tetragonal, orthorhombic, quasi-cubic, and/or similar crystal structure and may have a dielectric constant of 20 or more and 70 or less. The first metal oxide may be, for example, ZrO₂.

The first dielectric material layer may be formed by adsorbing a precursor of the first metal oxide onto the first electrode and then performing heat treatment. The precursor of the first metal oxide may be a first metal-containing organometallic compound. The precursor of the first metal oxide may be, for example, ZrCp₂Cl₂ or ZrCpₓMe₄₋ₓ, wherein Cp is a cyclopentadienyl group, Me is a methyl group, and x is 1 or 2. The adsorption of the precursor of the first metal oxide onto the first electrode may be performed at about 200° C. to about 300° C. The formation of the first metal oxide by heat-treating the adsorbed precursor on the first electrode may be performed at about 500° C. to about 700° C.

Referring to FIG. 16B, an impurity IM may be selectively adsorbed onto the grain boundaries GB of the first dielectric material layer 131. The impurity IM may include a nonmetal element belonging to Groups 1 to 17 in the Periodic Table of the Elements. For example, the impurity IM may include hydrogen, fluorine, chlorine, bromine, and/or a combination thereof. The impurity IM may have relatively higher selectivity for the grain boundaries GB compared to the grains GR. The impurity IM may be selectively adsorbed onto the grain boundaries GB through thermal decomposition of a precursor compound. The precursor compound may be, for example, SF₆, CF₄, or the like. The impurity IM may form chemical bonds on the grain boundaries GB. The selective adsorption of the impurity IM onto the grain boundaries GB may be performed at, for example, about 300° C. to about 500° C.

The selectivity of the impurity IM being adsorbed onto the grain boundaries GB may be, for example, 60% or more. The selectivity of the impurity IM may be expressed as the percentage of impurity IM atoms adsorbed onto the grain boundaries GB relative to the total number of impurity IM atoms adsorbed onto the first dielectric material layer 131.

Referring to FIG. 16C, a first metal-containing inhibitor IB may be selectively adsorbed onto a plurality of grains GR of a first dielectric material layer 131. In at least some embodiments, the first metal-containing inhibitor IB may include the based same material as the first dielectric material layer 131. The first metal-containing inhibitor IB may include, for example, a first metal-containing precursor compound. The first metal-containing precursor compound may include, for example, a first metal-containing organometallic compound. The first metal-containing precursor compound may be, for example, MCp₂Cl₂ or MCpₓMe₄₋ₓ, wherein Cp is a cyclopentadienyl group, Me is a methyl group, x is 1 or 2, and M is a metal element belonging to Groups 2 to 12 in the Periodic Table of the Elements. The first metal-containing precursor compound may be, for example, ZrCp₂Cl₂ or ZrCpₓMe₄₋ₓ wherein Cp is a cyclopentadienyl group, Me is a methyl group, and x is 1 or 2. The first metal-containing inhibitor IB may have relatively higher selectivity for the grains GR compared to the grain boundaries GB. The first metal-containing inhibitor IB may be selectively adsorbed onto the grains GR through heat treatment. The first metal-containing inhibitor IB may form chemical bonds on the grains GR. The selective adsorption of the first metal-containing inhibitor IB onto the plurality of grains GR of the first dielectric material layer 131 may be, for example, performed at about 200° C. to about 300° C.

Referring to FIG. 16D, alumina may be selectively introduced onto the grain boundaries GB. The selective adsorption of an aluminum oxide, e.g., alumina (Al₂O₃), on the grain boundaries GB may include selectively adsorbing an aluminum precursor on the grain boundaries GB, and oxidizing the adsorbed aluminum precursor. These processes may each be performed at about 200° C. to about 300° C. and may be carried out for two or more cycles. These processes may be performed by atomic layer deposition (ALD). The ALD may be conducted for one or more cycles, or two or more cycles. The aluminum precursor may be, for example, an aluminum-containing organometallic compound. The aluminum precursor may be, for example, Al(CH₃)₂(OC₃H₇), Al(OC₃H₇)₃, Al(CH₃)₃, or Al[OCH(CH₃)(C₂H₅)]₃. Oxidation of the aluminum precursor may be performed by supplying moisture. By selectively introducing alumina onto the grain boundaries GB, at least part of the impurity adsorbed onto the grain boundaries GB may be removed. After selectively introducing alumina onto the grain boundaries GB, some of the impurity adsorbed onto the grain boundaries GB may still remain.

Referring to FIG. 16E, the first metal-containing inhibitor IB may be oxidized to form the insertion layer 132. The oxidation of the first metal-containing inhibitor IB may be performed by supplying an oxidizing gas such as ozone (O₃). The oxidation of the first metal-containing inhibitor IB may be performed at about 200° C. to about 300° C. for about 10 seconds to about 200 seconds. Through the oxidation of the first metal-containing inhibitor IB, a first metal oxide may be formed. The first metal oxide may be, for example, zirconium oxide (ZrO₂). The insertion layer 132 may include an aluminum oxide selectively disposed on the grain boundaries GB of the first dielectric material layer 131 and may include the first metal oxide selectively disposed on the grains GR of the first dielectric material layer 131. Thereby, the insertion layer 132 may be referred to as including a base of a first metal oxide and an aluminum oxide disposed in the grain boundaries therebetween. The first metal oxide may include at least one first metal belonging to Groups 2 to 12 in the Periodic Table of the Elements. The aluminum oxide may include alumina. The insertion layer 132 may contain residual impurity IM. The content of the impurity IM within the insertion layer 132 may be more than 0 at % and less than 1 at %, as the ratio of the number of atoms of the impurity to the total number of atoms of the impurity IM and metal. The metal atoms may include aluminum and first metal atoms. Alternatively, the insertion layer 132 may substantially not include residual impurity IM. In at least some embodiments, the first dielectric material layer 131 may serve as a seed layer for a crystal growth during the formation of the insertion layer 132. As such, the grains and grain boundaries of the insertion layer 132 may match the grains and grain boundaries of the first dielectric material layer 131.

Referring to FIG. 16F, a second dielectric material layer 133 may be provided on the insertion layer 132. The second dielectric material layer 133 may be provided in a manner similar to the first dielectric material layer 131. However, the heat treatment temperature of the second dielectric material layer 133 may be performed at a lower temperature, about 300° C. to about 500° C., compared to the heat treatment temperature of the first dielectric material layer 131. By providing the second dielectric material layer 133 on the insertion layer 132, a dielectric layer 130 with a structure of first dielectric material layer 131/insertion layer 132/second dielectric material layer 133 may be formed. By selectively arranging alumina on the grain boundaries GB of the first dielectric material layer 131 in the insertion layer 132, the aluminum content introduced into the insertion layer 132 decreases, and as a result, the overall reduction in the dielectric constant of the dielectric layer 130 may be suppressed, and the flow of leakage current through the grain boundaries GB may be inhibited. In at least some embodiments, the insertion layer 132 may serve as a seed layer for a crystal growth during the formation of the second dielectric material layer 133. As such, the grains and grain boundaries of the insertion layer 132 may match the grains and grain boundaries of the second dielectric material layer 133.

Referring to FIG. 16G, a second electrode 120 may be provided on the second dielectric material layer 133. By placing the second electrode 120 on the second dielectric material layer 133, the capacitor 100 may be prepared.

The second electrode 120 may be selected from the materials used for the first electrode 110. The second electrode may be, for example, an aluminum (Al) metal electrode.

Hereinafter, one or more embodiments will be described in greater detail with reference to the following examples. However, it will be understood that these examples are provided only to illustrate the present disclosure, and not intended to limit the scope of the one or more embodiments of the present specification.

### (Preparation of the Dielectric)

### Example 1: Capacitor Containing ZrO₂ Insertion Layer with Selectively Deposited Al₂O₃

A crystallized ZrO₂ first dielectric material layer with a thickness of 3 nanometers (nm was formed on a TiN first electrode having a thickness of 50 nm. The surface of the crystallized ZrO₂ layer included grains and grain boundaries.

By supplying the zirconium precursor CpZr(N(CH₃)₂)₃ (Cp: cyclopentadiene) at 250° C. onto the TiN electrode, the zirconium precursor was adsorbed onto the TIN electrode. The zirconium precursor was heat-treated at 600° C. for 60 seconds to form a crystallized ZrO₂ first dielectric material layer.

On the ZrO₂ layer, by supplying SF₆ gas at 400° C., fluorine (F) was selectively adsorbed onto the grain boundaries of ZrO₂ to form a fluorine-introduced ZrO₂ layer.

On the fluorine-introduced ZrO₂ layer, by supplying the zirconium precursor CpZr(N(CH₃)₂)₃ (Cp: cyclopentadiene) as an inhibitor at 250° C., the zirconium precursor was selectively adsorbed onto the grains on the surface of the ZrO₂ layer.

While supplying the aluminum precursor Al(CH₃)₂(OC₃H₇) at 250° C. onto the fluorine and zirconium precursor-introduced ZrO₂ layer, the aluminum precursor was selectively adsorbed onto the grain boundaries of the ZrO₂ layer. Subsequently, by supplying water (H₂O), the aluminum precursor was oxidized to form alumina (Al₂O₃). The alumina was selectively formed on the grain boundaries. The introduction of alumina onto the grain boundaries of the ZrO₂ layer was performed by atomic layer deposition (ALD). The introduction of the aluminum precursor and oxidization of the aluminum precursor to form alumina were performed in twice (i.e., two cycles). As alumina was formed on the grain boundaries of the ZrO₂ layer surface, at least part of the fluorine adsorbed on the grain boundaries was removed.

By supplying ozone (O₃) at 250° C. for 60 seconds onto the zirconium precursor and alumina-introduced ZrO₂ layer, the zirconium precursor was oxidized to selectively form alumina (Al₂O₃) on the grain boundaries and selectively form zirconium oxide (ZrO₂) on the grains, thereby forming an insertion layer.

By supplying the zirconium precursor CpZr(N(CH₃)₂)₃ (Cp: cyclopentadiene) at 250° C. onto the insertion layer, the zirconium precursor was adsorbed onto the insertion layer. The zirconium precursor was heat-treated at 400° C. for 60 seconds to form a crystallized ZrO₂ second dielectric material layer.

By depositing an Al second electrode with a thickness of 100 nm on the ZrO₂ second dielectric material layer, the capacitor was fabricated.

The dielectric layer had a structure of a first dielectric material layer (ZrO₂)/insertion layer (ZrO₂ with selectively deposited Al₂O₃)/second dielectric material layer (ZrO₂). The insertion layer included less than 1 at % of fluorine (F) as an impurity.

### Comparative Example 1: Capacitor containing Al₂O₃ Insertion Layer

A crystallized ZrO₂ first dielectric material layer with a thickness of 3 nm was formed on a TiN first electrode having a thickness of 50 nm. The surface of the crystallized ZrO₂ layer included grains and grain boundaries.

By supplying the zirconium precursor CpZr(N(CH₃)₂)₃ (Cp: cyclopentadiene) at 250° C. onto the TiN electrode, the zirconium precursor was adsorbed onto the TiN electrode. The zirconium precursor was heat-treated at 600° C. for 60 seconds to form a crystallized ZrO₂ first dielectric material layer.

By supplying the aluminum precursor Al(CH₃)₂(OC₃H₇) at 250° C. onto the ZrO₂ layer, the aluminum precursor was adsorbed. Subsequently, by supplying water (H₂O), the aluminum precursor was oxidized to form alumina (Al₂O₃) to form an insertion layer. The insertion layer was formed on the entire ZrO₂ layer. The introduction of alumina onto the ZrO₂ layer was performed by atomic layer deposition (ALD). The introduction of the aluminum precursor and oxidization of the aluminum precursor to form alumina were performed twice (i.e., in two cycles).

By supplying the zirconium precursor CpZr(N(CH₃)₂)₃ (Cp: cyclopentadiene) at 250° C. onto the insertion layer, the zirconium precursor was adsorbed onto the insertion layer. The zirconium precursor was heat-treated at 400° C. for 60 seconds to form a crystallized ZrO₂ second dielectric material layer.

By depositing an Al second electrode with a thickness of 100 nm on the ZrO₂ second dielectric material layer, the capacitor was fabricated.

The dielectric layer had a structure of a first dielectric material layer (ZrO₂)/insertion layer (Al₂O₃)/second dielectric material layer (ZrO₂).

### Evaluation Example 1: Leakage Current Measurement

Leakage current was measured for the capacitors prepared in Example 1 and Comparative Example 1.

The leakage current is the current density when a voltage of 1V is applied to the capacitor. The measurement results are shown in Table 1.

TABLE 1

| | Leakage current [amps per | Dielectric |
|---|---|---|
| Interlayer | centimeters squared (A/cm²)] | constant (k) |
| Example 1 | 3.54 × 10⁻⁵ | 15.1 |
| Comparative Example 1 | 3.12 × 10⁻⁵ | 13.8 |

As shown in Table 1, the capacitor of Example 1, which includes an insertion layer where alumina is selectively introduced at the grain boundaries known to cause leakage current, exhibited a dielectric constant increase of more than 9% while maintaining similar leakage current compared to the capacitor of Comparative Example 1, which has a uniform alumina insertion layer introduced between the dielectrics.

### Evaluation Example 2: Confirmation of Fluorine Selectivity for Grain Boundaries

By supplying the zirconium precursor CpZr(N(CH₃)₂)₃ (Cp: cyclopentadiene) at 250° C. onto the TiN electrode having a thickness of 50 nm, the zirconium precursor was adsorbed onto the TiN electrode. The zirconium precursor was heat-treated at 600° C. for 60 seconds to form a crystallized ZrO₂ first dielectric material layer with a thickness of 10 nm.

By supplying SF₆ gas at 400° C. onto the ZrO₂ layer, fluorine (F) was selectively adsorbed onto the grain boundaries of ZrO₂ to form a fluorine-introduced ZrO₂ layer.

SEM/EDS analysis of the surface of the fluorine-introduced ZrO₂ layer confirmed that fluorine is disposed on the grain boundaries.

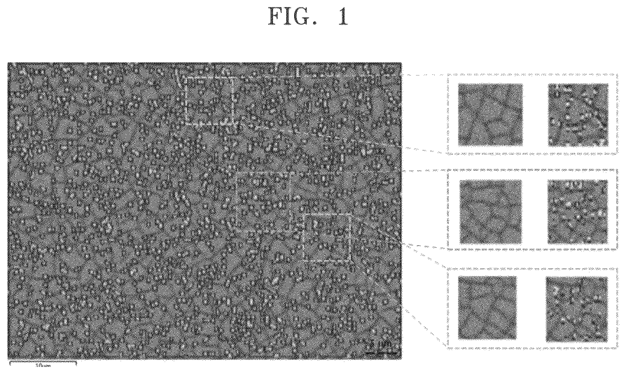

FIG. 1 is a scanning electron microscope image of the surface of the fluorine-introduced ZrO₂ layer. In FIG. 1, the portions indicated by black lines are grain boundaries (GB), and the gray regions therebetween are grains (GR). The dots on the surface of ZrO₂ layer represent fluorine (F). As shown in FIG. 1, it was confirmed that fluorine is selectively disposed on the grain boundaries. It was confirmed that out of 1,310 fluorine atoms, 866 fluorine atoms were located on the grain boundaries. The proportion of fluorine atoms located on the grain boundaries was 66.1% of the total fluorine atoms.

### Evaluation Example 3: XPS Analysis

The fluorine content introduced was measured via XPS analysis on the surface of the fluorine-introduced ZrO₂ layer prepared in Evaluation Example 2, and on the surface etched by sputtering at 1,000 eV for 10 seconds on the same surface.

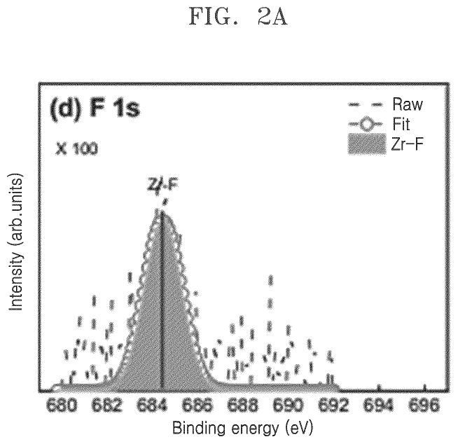

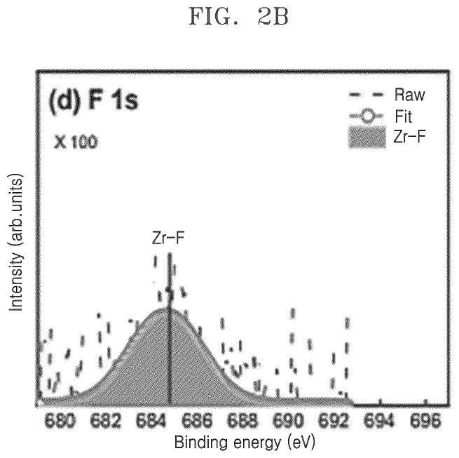

FIG. 2A is an image showing the XPS analysis profile of the F 1s orbital on the surface of the fluorine-introduced ZrO₂ layer.

FIG. 2B is an image showing the XPS analysis profile of the F Is orbital on the etched surface after sputtering at 1,000 eV for 10 seconds on the fluorine-introduced ZrO₂ layer surface.

As shown in FIGS. 2A and 2B, peaks indicating Zr—F bonds appeared near 685 eV.

In FIG. 2A, the fluorine content was 5%, and in FIG. 2B, the fluorine content was 1.66%.

In contrast, when SF₆ gas was supplied at 400° C. onto the amorphous ZrO₂ layer, fluorine (F) was not introduced into the layer.

No peaks indicating Zr—F bonds were observed in the XPS analysis measured after supplying SF₆ gas at 400° C. onto the amorphous ZrO₂ layer.

### Evaluation Example 4-1: Calculation of Reaction Selectivity of Fluorine (F)

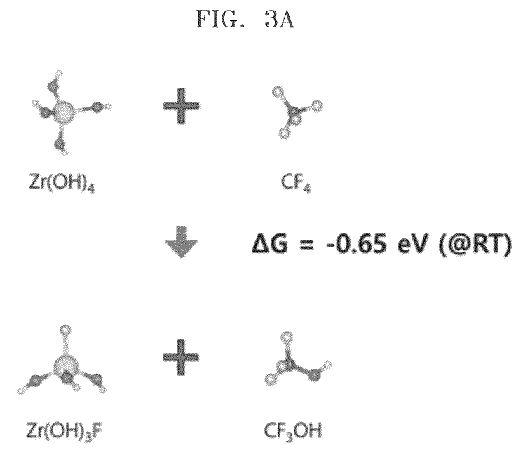

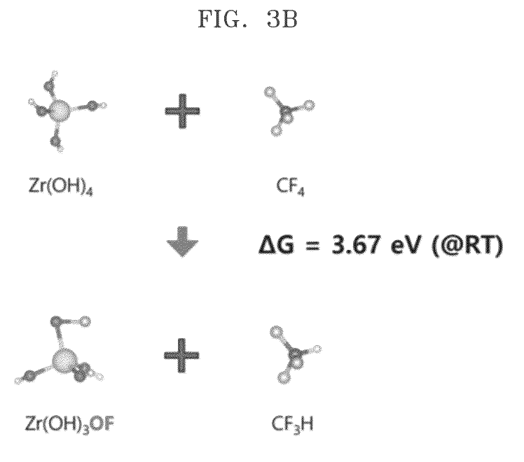

Using Density Functional Theory (DFT), it was calculated whether it is energetically favorable to introduce fluorine (F) onto the surface of the ZrO₂ layer prepared in Evaluation Example 2. The calculation results are shown in FIGS. 3A and 3B.

As shown in FIG. 3A, the Gibbs free energy (ΔG) of the reaction forming Zr(OH)₃F+CF₃OH from Zr(OH)₄+CF₄ was −0.65 eV at room temperature.

As shown in FIG. 3B, the Gibbs free energy (ΔG) of the reaction forming Zr(OH)₃OF+CF₃H from Zr(OH)₄+CF₄ was 3.67 eV at room temperature.

It was confirmed that forming Zr—F bonds is easier than forming Zr—OF bonds on the surface of the ZrO₂ layer.

### Evaluation Example 4-2: Calculation of Reaction Selectivity of Zirconium Precursor (Inhibitor)

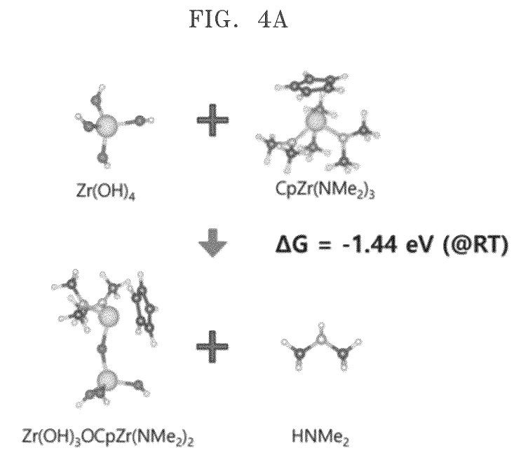

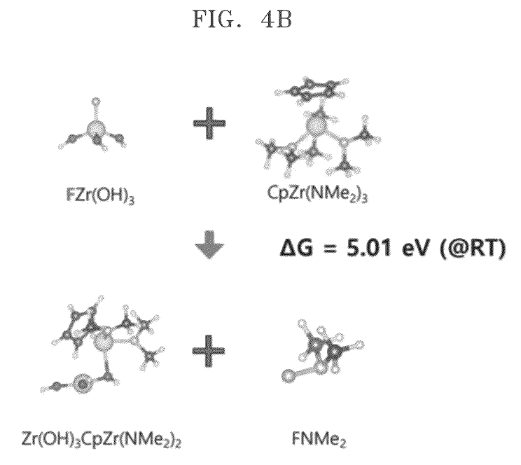

Using Density Functional Theory (DFT), it was calculated whether it is energetically favorable to introduce a zirconium precursor (CpZr(N(CH₃)₂) 3) onto the surface of the fluorine-introduced ZrO₂ layer prepared in Evaluation Example 2. The calculation results are shown in FIGS. 4A and 4B.

As shown in FIG. 4A, the Gibbs free energy (ΔG) of the reaction forming Zr(OH)₃OCpZr(N(CH₃)₂)₂+HN(CH₃)₂ from Zr(OH)₄+CpZr(N(CH₃)₂)₃ was −1.44 eV at room temperature.

As shown in FIG. 4B, the Gibbs free energy (ΔG) of the reaction forming Zr(OH)₃CpZr(N(CH₃)₂)₂+FN(CH₃)₂ from FZr(OH)₃+CpZr(N(CH₃)₂)₃ was 5.01 eV at room temperature.

It was confirmed that the adsorption of the zirconium precursor is easier on the surface of the ZrO₂ layer without fluorine introduced, compared to the fluorine-introduced ZrO₂ layer surface.

It was confirmed that on the ZrO₂ layer, the zirconium precursor can adsorb more readily onto fluorine-free grains compared to fluorine-introduced grain boundaries.

### Evaluation Example 4-3: Calculation of Reaction Selectivity of Aluminum Precursor

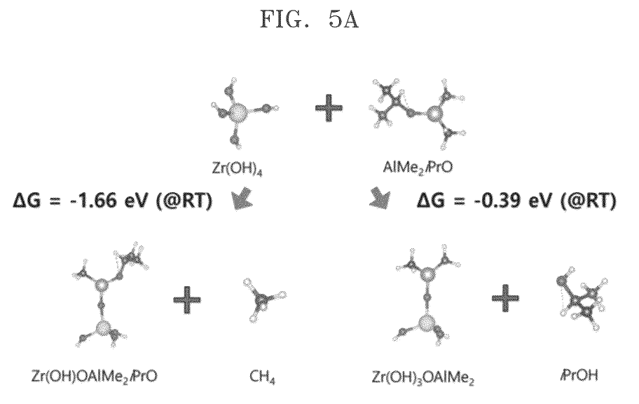

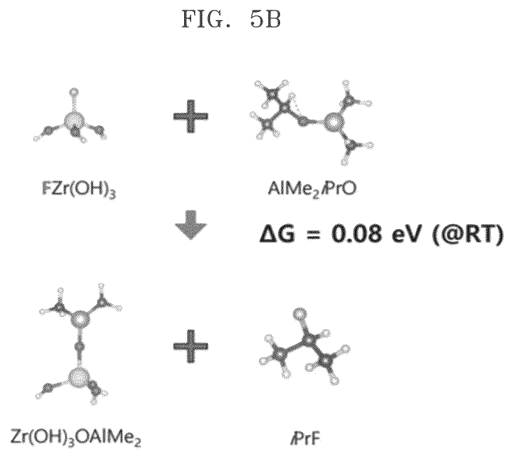

Using Density Functional Theory (DFT), it was calculated whether it is energetically favorable to introduce an aluminum precursor (Al(CH₃)₂(OC₃H₇)) onto the surface of the ZrO₂ layer into which fluorine and zirconium precursors were introduced in Evaluation Example 2. The calculation results are shown in FIGS. 5A and 5B.

As shown in FIG. 5A, the Gibbs free energy (ΔG) at room temperature for the reaction forming Zr(OH)₃OAl(CH₃)₂(OC₃H₇)+CH₄ from Zr(OH)₄+Al(CH₃)₂(OC₃H₇) was −1.66 eV.

As also shown in FIG. 5A, the Gibbs free energy (ΔG) at room temperature for the reaction forming Zr(OH)₃OAl(CH₃)₂+HOC₃H₇ from Zr(OH)₄+Al(CH₃)₂(OC₃H₇) was-0.39 eV.

As shown in FIG. 5B, the Gibbs free energy (ΔG) at room temperature for the reaction forming Zr(OH)₃OAl(CH₃)₂+FOC₃H₇ from FZr(OH)₃+Al(CH₃)₂(OC₃H₇) was 0.08 eV.

It was confirmed that the adsorption of the aluminum precursor is easier on the surface of the fluorine-introduced ZrO₂ layer compared to the surface of the fluorine-free ZrO₂ layer.

It was confirmed that on the ZrO₂ layer, the aluminum precursor can adsorb more readily onto fluorine-introduced grain boundaries compared to fluorine-free grains.

The above-described capacitor and the electronic device including the same have been described with reference to the embodiments shown in the drawings; however, these are merely illustrative, and it will be understood by those skilled in the art that various modifications and equivalent other embodiments are possible therefrom. Therefore, the disclosed embodiments should be considered in a descriptive sense rather than a limiting sense. The scope of rights is indicated by the claims rather than the foregoing description, and all differences within the equivalent scope are to be construed as included within the scope of rights.

According to one aspect, by including an impurity and an aluminum oxide in the insertion layer, the leakage current of the capacitor is reduced and the decrease in dielectric constant is suppressed.

According to another aspect, by selectively arranging the aluminum oxide of the insertion layer on the grain boundaries of the dielectric layer, the leakage current of the capacitor is reduced and the decrease in dielectric constant is suppressed.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A capacitor comprising:
a first electrode;
a second electrode opposing the first electrode; and
a dielectric layer between the first electrode and the second electrode the dielectric layer including an insertion layer in the dielectric layer such that the insertion layer is spaced apart from the first and second electrodes,
wherein the insertion layer includes an impurity and an aluminum oxide,
wherein the impurity includes a nonmetal element belonging to Group 1 or Group 17 in the Periodic Table of the Elements, and
wherein a content of the impurity is greater than 0 atomic percent (at %) and less than 1 at %, as a ratio of atoms of the impurity to a total number of atoms of the impurity and metals within the insertion layer.

2. The capacitor of claim 1,
wherein the impurity includes at least one of hydrogen, fluorine, chlorine, or bromine.

3. The capacitor of claim 1,
wherein the aluminum oxide includes AlₐO_{b}, wherein 1.0≤a≤3.0 and 2.0≤b≤4.0.

4. The capacitor of claim 3,
wherein the insertion layer further includes a dielectric material,
wherein the dielectric material includes a first metal oxide,
wherein the first metal oxide includes an oxide of at least one of titanium (Ti), hafnium (Hf), zirconium (Zr), silicon (Si), lanthanum (La), gadolinium (Gd), strontium (Sr), yttrium (Y), niobium (Nb), tantalum (Ta), chromium (Cr), copper (Cu), iron (Fe), magnesium (Mg), nickel (Ni), scandium (Sc), germanium (Ge), cerium (Ce), praseodymium (Pr), neodymium (Nd), samarium (Sm), europium (Eu), dysprosium (Dy), holmium (Ho), erbium (Er), thulium (Tm), ytterbium (Yb), or lutetium (Lu).

5. The capacitor of claim 4,
wherein the first metal oxide includes M_{c}O_{d}, wherein 1.0≤c≤3.0 and 2.0≤d≤5.0,
wherein M includes at least one of titanium (Ti), hafnium (Hf), zirconium (Zr), silicon (Si), lanthanum (La), gadolinium (Gd), strontium (Sr), yttrium (Y), niobium (Nb), tantalum (Ta), chromium (Cr), copper (Cu), iron (Fe), magnesium (Mg), nickel (Ni), scandium (Sc), or germanium (Ge).

6. The capacitor of claim 4, wherein the first metal oxide includes at least one of ZrO₂, HfO₂, ZrₓHf_{y}O₂ (0<x<1, 0<y<1), TiO₂, SiO₂, La₂O₃, GdO₂, SrO₂, Y₂O₃, La₂O₃, Nb₂O₅, Ta₂O₅, Cr₂O₃, CuO, Fe₂O₃, MgO, Nb₂O₅, NiO, Ta₂O₅, Sc₂O₃, CeO₂, PrOₓ (1≤x≤5), Nd₂O₃, Sm₂O₃, EuO_{y} (1≤y≤5), Gd₂O₃, Dy₂O₃, Ho₂O₃, Er₂O₃, Tm₂O₃, Yb₂O₃, or Lu₂O₃.

7. The capacitor of claim 4,
wherein the insertion layer includes the aluminum oxide and the first metal oxide,
wherein a content of the first metal of the first metal oxide is higher than a content of the aluminum of the aluminum oxide in the insertion layer.

8. The capacitor of claim 7,
wherein the content of the aluminum is 10 at % or less, as a ratio of atoms of the aluminum to the total number of atoms of the impurity and metals within the insertion layer.

9. The capacitor of claim 1,
wherein the insertion layer includes AlₐM_{b}O₃, wherein 0<a<1 and 0<b<2, wherein M is a metal belonging to Groups 2 to 12 in the Periodic Table of the Elements, and
a ratio of aluminum (a) to M (b) in the insertion layer satisfies 0<a/b≤0.1.

10. The capacitor of claim 1,
wherein the insertion layer includes at least one of Al_{c}Zr_{d}O₃, Al_{c}Hf_{d}O₃, Al_{c}Zr_{d}HfₑO₃, Al_{c}Ti_{d}O₃ Al_{c}Zr_{d}TiₑO₃, Al_{c}Hf_{d}TiₑO₃, wherein 0<c<1, 0<d<2, and 0<e<2.

11. The capacitor of claim 1, wherein the dielectric layer further includes
a first dielectric material layer adjacent to the first electrode; and
a second dielectric material layer adjacent to the second electrode,
wherein the insertion layer is between the first dielectric material layer and the second dielectric material layer,
wherein the insertion layer further includes a dielectric material,
wherein the dielectric material, the first dielectric material layer, and the second dielectric material layer share a same first metal oxide.

12. The capacitor of claim 11,
wherein a content of the aluminum within the insertion layer is higher than a content of the aluminum at a boundary region between the first dielectric material layer and the insertion layer, and
wherein the content of the aluminum within the insertion layer is higher than a content of the aluminum at a boundary region between the second dielectric material layer and the insertion layer.

13. The capacitor of claim 1,
wherein the dielectric layer comprises a crystalline dielectric material, and
wherein a thickness of the dielectric layer is 10 nanometers (nm)) or less, and
a thickness of the insertion layer is 5 nm or less.

14. The capacitor of claim 1,
wherein the first electrode and the second electrode each independently include at least one conductive material including at least one of titanium (Ti), nickel (Ni), aluminum (Al), tantalum (Ta), tungsten (W), platinum (Pt), palladium (Pd), gold (Au), iridium (Ir), rhodium (Rh), molybdenum (Mo), vanadium (V), niobium (Nb), ruthenium (Ru), cobalt (Co), a conductive metal oxide, or a conductive metal nitride.

15. An electronic device comprising:
a transistor; and
a capacitor electrically connected to the transistor,
wherein the capacitor comprises
a first electrode,
a second electrode opposing the first electrode, and
a dielectric layer between the first electrode and the second electrode, the dielectric layer including an insertion layer in the dielectric layer such that the insertion layer is spaced apart from the first and second electrodes,
wherein the insertion layer includes an impurity,
wherein the impurity includes a nonmetal element belonging to Group 1 or Group 17 in the Periodic Table of the Elements, and
wherein a content of the impurity is greater than 0 atomic percent (at %) and less than 1 at %, as a ratio of atoms of the impurity to a total number of atoms of the impurity and metal within the insertion layer.

16. A method of preparing a capacitor, the method comprising:
providing a crystallized first dielectric material layer, a surface of the first dielectric material layer including a plurality of grains and grain boundaries therebetween;
selectively adsorbing an impurity onto the grain boundaries;
selectively adsorbing a first metal-containing inhibitor onto the plurality of grains;
selectively introducing an aluminum oxide onto the grain boundaries;
forming an insertion layer by oxidizing the first metal-containing inhibitor; and
providing a second dielectric material layer on the insertion layer,
wherein the impurity includes a nonmetal element belonging to Group 1 or Group 17 in the Periodic Table of the Elements.

17. The method of claim 16,
wherein the impurity includes at least one of hydrogen, fluorine, chlorine, or bromine.

18. The method of claim 16,
wherein the selectively introducing the aluminum oxide onto the grain boundaries includes atomic layer deposition (ALD), and
wherein the ALD is performed for one or more cycles.

19. The method of claim 18,
wherein the selectively introducing the aluminum oxide onto the grain boundaries includes
selectively introducing an aluminum precursor onto the grain boundaries; and
oxidizing the aluminum precursor.

20. The method of claim 16,
wherein the forming the insertion layer results in the insertion layer including an aluminum oxide and a first metal oxide,
wherein the first metal oxide includes at least one first metal belonging to Groups 2 to 12 in the Periodic Table of the Elements.
